(19) United States
(12) Patent Application Publication
(10) Pub. No.: US 2007/0075362 A1
(43) Pub. Date: Apr. 5, 2007

(54) Self-aligned schottky-barrier clamped trench DMOS transistor structure and its manufacturing methods

(76) Inventor: Ching-Yuan Wu, Hsinchu (TW)

Correspondence Address: LOWE HAUPTMAN BERNER, LLP, 1700 DIAGONAL ROAD, SUITE 300, ALEXANDRIA, VA, 22314, US

(21) Appl. No.: 11/239,149

(22) Filed: Sep. 30, 2005

(51) Int. Cl. H01L 29/76; H01L 29/94; H01L 31/00

(52) U.S. Cl. 257/335

(57) ABSTRACT

The self-aligned Schottky-barrier clamped trench DMOS transistor structure of the present invention comprises a Schottky-barrier diode being formed in a middle semiconductor portion of a self-aligned source region. The self-aligned source region comprises a lightly-doped epitaxial semiconductor layer, a moderately-doped base diffusion ring being formed in a surface portion of the lightly-doped epitaxial semiconductor layer surrounded by a trench gate region, a heavily-doped source diffusion ring being formed in a side surface portion of the moderately-doped base diffusion ring, and a self-aligned source contact being formed on a semiconductor surface of the self-aligned source region surrounded by a sidewall dielectric spacer. The trench gate region comprises a self-aligned conductive gate layer being formed over a gate dielectric layer lined over a trenched semiconductor surface in a shallow trench with or without a thicker isolation dielectric layer being formed on a bottom surface of the shallow trench.

### BACKGROUND OF THE INVENTION

1. Field of the Invention

The present invention is generally related to a trench DMOS transistor structure and its manufacturing methods and, more particularly, to a self-aligned Schottky-barrier clamped trench DMOS transistor structure and its manufacturing methods.

2. Description of the Prior Art

A DMOS (double-diffused metal-oxide-semiconductor) power transistor with a low turn-on resistance becomes an important semiconductor device for applications in battery protection, switching, linear regulator, amplifier and power management.

FIG. 1A shows a schematic cross-sectional view for a non-self-aligned source structure of a prior-art planar DMOS transistor, in which a p-body diffusion region 104a is formed in a lightly-doped N⁻ epitaxial silicon layer 101 formed on a heavily-doped N⁺ silicon substrate 100 through a patterned window surrounded by a patterned polycrystalline-silicon gate layer 103a on a gate oxide layer 102a by using a first masking photoresist step (not shown); a heavily-doped p⁺ diffusion region 105a is formed within the p-body diffusion region 104a through the patterned window by using a high-energy ion implantation; a heavily-doped n⁺ source diffusion ring 106a is formed in a surface portion of the p-body diffusion region 104a and on a side surface portion of the heavily-doped p⁺ diffusion region 105a through a non-self-aligned implantation window formed between a patterned photoresist layer (not shown) being formed in a middle portion of the patterned window and the patterned polycrystalline-silicon gate layer 103a on the gate oxide layer 102a by using a second masking photoresist step (not shown); a non-self-aligned source contact window is formed through an etching hole surrounded by a patterned oxide layer 107a through a third masking photoresist step (not shown); and a source contact metal layer 108a is formed over the patterned oxide layer 107a and on a semiconductor surface formed by the heavily-doped p⁺ diffusion region 105a surrounded by the heavily-doped n⁺ source diffusion ring 106a and a side surface portion of the heavily-doped n⁺ source diffusion ring 106a. Apparently, the non-self-aligned source structure of the planar DMOS power transistor shown in FIG. 1A needs two critical masking photoresist steps (second and third masking photoresist steps). However, misalignments of the two critical masking photoresist steps may produce non-uniform current flow distribution, resulting in serious device reliability issues. Therefore, it is difficult to scale down source area of the planar DMOS power transistor. Moreover, the patterned polycrystalline-silicon gate layer 103a being acted as a gate-interconnection conductive layer may have a higher gate-interconnection parasitic resistance to reduce switching speed if the interconnected transistor cell is large. A typical example for the planar DMOS power transistor can refer to U.S. Pat. No. 5,268,586 disclosed by S. Mukherjee et al.

FIG. 1B shows an equivalent device representation of the planar DMOS power transistor shown in FIG. 1A, in which a p-n junction diode (D1) is formed between source and drain electrodes through the p-body diffusion region 104a and the lightly-doped N⁻ epitaxial silicon layer 101. This p-n junction diode (D1) will be turned on in certain circuit applications-and minority-carrier storage of a forwardly-biased p-n junction diode may largely reduce switching speed of the planar DMOS power transistor. Therefore, a Schottky-barrier diode had been proposed to form between the source and drain electrodes.

Several complicate methods had been proposed to simultaneously integrate a planar DMOS transistor and a Schottky-barrier diode in a transistor cell. A typical example can refer to U.S. Pat. No. 6,686,614 disclosed by J. Tihanji and is shown in FIG. 2A and FIG. 2B, in which FIG. 2A shows a schematic cross-sectional view and FIG. 2B shows an equivalent device representation. From FIG. 2A, a Schottky-barrier diode (Ds) shown in FIG. 2B is formed on a lightly-doped N⁻ epitaxial silicon layer 20 through a non-self-aligned trench window formed in a middle portion of a p-body diffusion region 50. It is clearly seen that there is no diffusion guard ring formed for Schottky-barrier contact metal 90 to eliminate edge leakage and soft breakdown; the p-body diffusion region 50 is floating and isn't shorted to a heavily-doped n⁺ source diffusion ring 60; the non-self-aligned trench window formed may produce non-uniform current flow distribution for nearby planar DMOS transistor cells; and the Schottky-barrier diode with a low barrier height may produce a large reverse leakage current in a forward blocking state.

It is, therefore, a major objective of the present invention to offer a self-aligned Schottky-barrier clamped trench DMOS transistor structure without using critical masking photoresist steps.

It is another objective of the present invention to offer a self-aligned Schottky-barrier clamped trench DMOS transistor structure with a moderately-doped p-base diffusion ring of a trench DMOS transistor cell being acted as a diffusion guard ring of a Schottky-barrier diode to eliminate edge leakage current and soft breakdown.

It is a further objective of the present invention to offer a self-aligned Schottky-barrier clamped trench DMOS transistor structure with the moderately-doped p-base diffusion ring being shorted to a heavily-doped n⁺ source diffusion ring of the trench DMOS transistor cell to eliminate the body effect.

It is an important objective of the present invention to offer a self-aligned Schottky-barrier clamped trench DMOS transistor structure with the Schottky-barrier diode being pinched by a p-n junction depletion region formed between the moderately-doped p-base diffusion ring and a lightly-doped N⁻ epitaxial silicon layer to eliminate a reverse leakage current of the Schottky-barrier diode with a low barrier height in a forward blocking state.

### SUMMARY OF THE INVENTION

The present invention discloses a self-aligned Schottky-barrier clamped trench DMOS transistor structure and its manufacturing methods, in which a Schottky-barrier diode is integrated with each of trench DMOS transistor cells in a self-aligned manner. The self-aligned Schottky-barrier clamped trench DMOS transistor structure of the present invention comprises a self-aligned source region and a trench gate region, wherein the self-aligned source region is surrounded by the trench gate region. The self-aligned source region comprises a moderately-doped p-base diffusion ring being formed in a lightly-doped N⁻ epitaxial semiconductor layer surrounded by the trench gate region, a heavily-doped n⁺ source diffusion ring being formed within the moderately-doped p-base diffusion ring, a self-aligned source contact window being formed on the lightly-doped N⁻ epitaxial semiconductor layer surrounded by the moderately-doped p-base diffusion ring, the moderately-doped p-base diffusion ring being surrounded by the heavily-doped n⁺ source diffusion ring, and the heavily-doped n⁺ source diffusion ring being surrounded by a sidewall dielectric spacer formed over a sidewall of the trench gate region and on a side surface portion of a buffer dielectric layer in the self-aligned source region, and a self-aligned metal silicide layer being formed on the self-aligned source contact window. The trench gate region comprises a self-aligned conductive gate layer being formed over a gate dielectric layer lined over a trenched semiconductor surface in a shallow trench with or without a thicker isolation dielectric layer being formed on a bottom trenched semiconductor surface of the shallow trench. The self-aligned conductive gate layer comprises a self-aligned heavily-doped polycrystalline-silicon gate layer, a self-aligned heavily-doped polycrystalline-silicon gate layer capped with a metal silicide layer, or a self-aligned trenched heavily-doped polycrystalline-silicon gate layer refilled with a refractory metal or metal silicide layer. The moderately-doped p-base diffusion ring is acted as a diffusion guard ring of a self-aligned Schottky-barrier contact to eliminate edge leakage current and soft breakdown of the Schottky-barrier diode. The self-aligned Schottky-barrier clamped n-channel trench DMOS transistor structure as described can be easily extended to form self-aligned Schottky-barrier clamped p-channel trench DMOS transistor structure by changing doping types in semiconductor regions. Moreover, the self-aligned Schottky-barrier clamped trench DMOS transistor structures can be used to fabricate insulated-gate bipolar transistors (IGBT) or MOS-controlled thyristors (MCT).

### BRIEF DESCRIPTION OF THE DRAWINGS

FIG. 1A and FIG. 1B show schematic diagrams of a prior art planar DMOS transistor structure, in which FIG. 1A shows its schematic cross-sectional view and FIG. 1B shows its equivalent device representation.

FIG. 2A and FIG. 2B show schematic diagrams of a prior-art planar DMOS transistor structure integrated with a Schottky-barrier diode, in which FIG. 2A shows its schematic cross-sectional view and FIG. 2B shows its equivalent device representation.

FIG. 3A through FIG. 3G show process steps and their schematic cross-sectional views of fabricating a first-type self-aligned Schottky-barrier clamped trench DMOS transistor structure of the present invention.

FIG. 4A through FIG. 4E show simplified process steps after FIG. 3B and their schematic cross-sectional views of fabricating a second-type self-aligned Schottky-barrier clamped trench DMOS transistor structure of the present invention.

FIG. 5A and FIG. 5B show simplified process steps after FIG. 3C and their schematic cross-sectional views of fabricating a third-type self-aligned Schottky-barrier clamped trench DMOS transistor structure of the present invention.

FIG. 6A and FIG. 6B show simplified process steps after FIG. 3C and their schematic cross-sectional views of fabricating a fourth-type self-aligned Schottky-barrier clamped trench DMOS transistor structure of the present invention.

FIG. 7A and FIG. 7B show simplified process steps after FIG. 4B and their schematic cross-sectional views of fabricating a fifth-type self-aligned Schottky-barrier clamped trench DMOS transistor structure of the present invention. FIG. 8A and FIG. 8B show simplified process steps after FIG. 4B and their schematic cross-sectional views of fabricating a sixth-type self-aligned Schottky-barrier clamped trench DMOS transistor structure of the present invention.

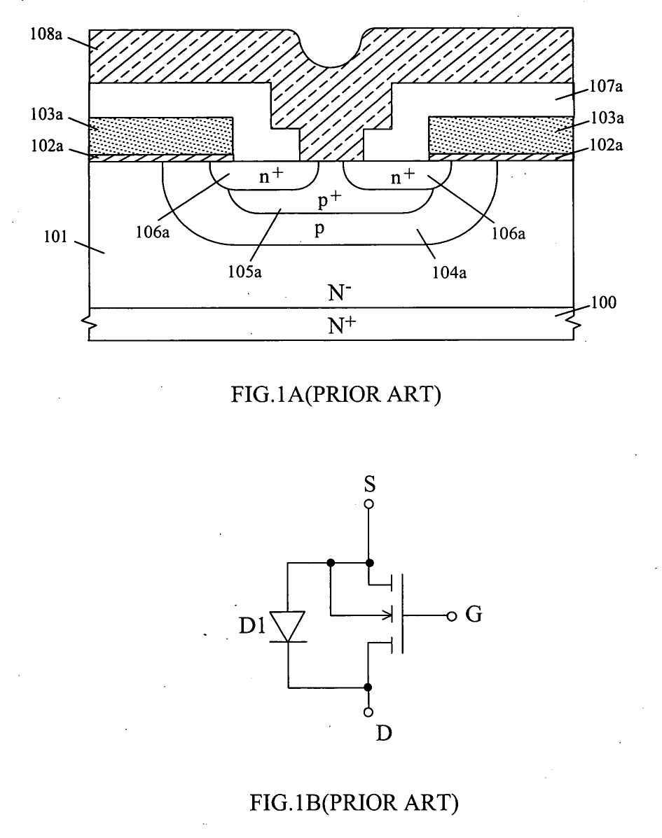

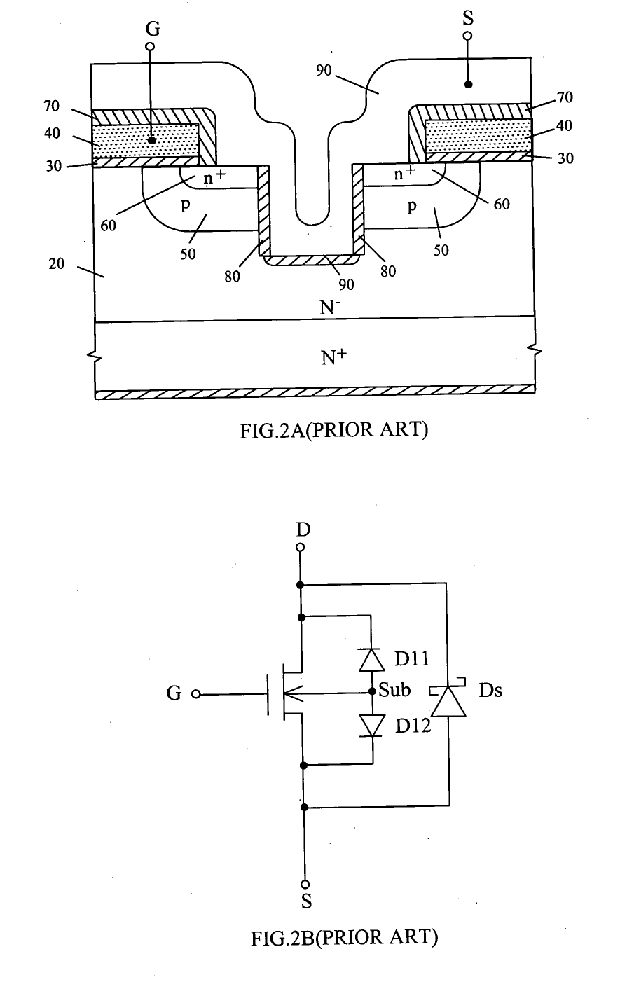

### DETAILED DESCRIPTION OF THE PREFERRED EMBODIMENTS

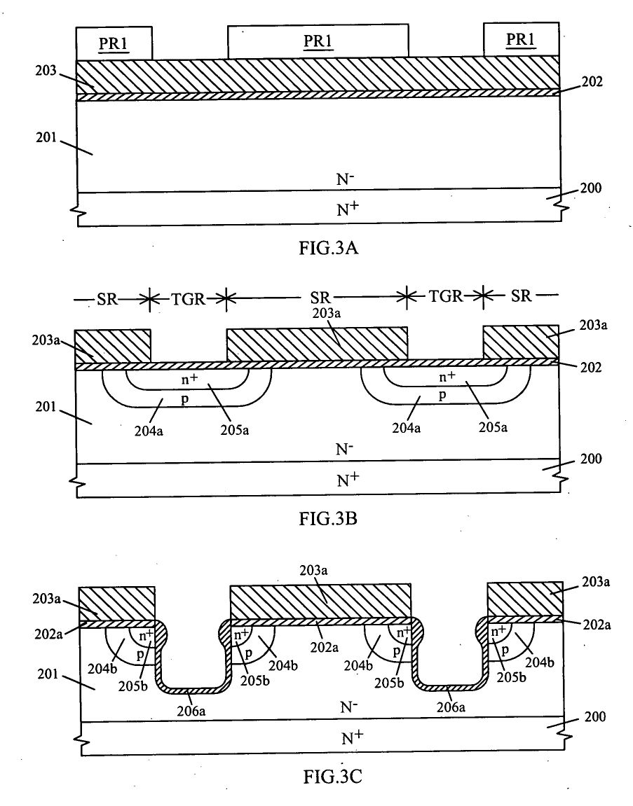

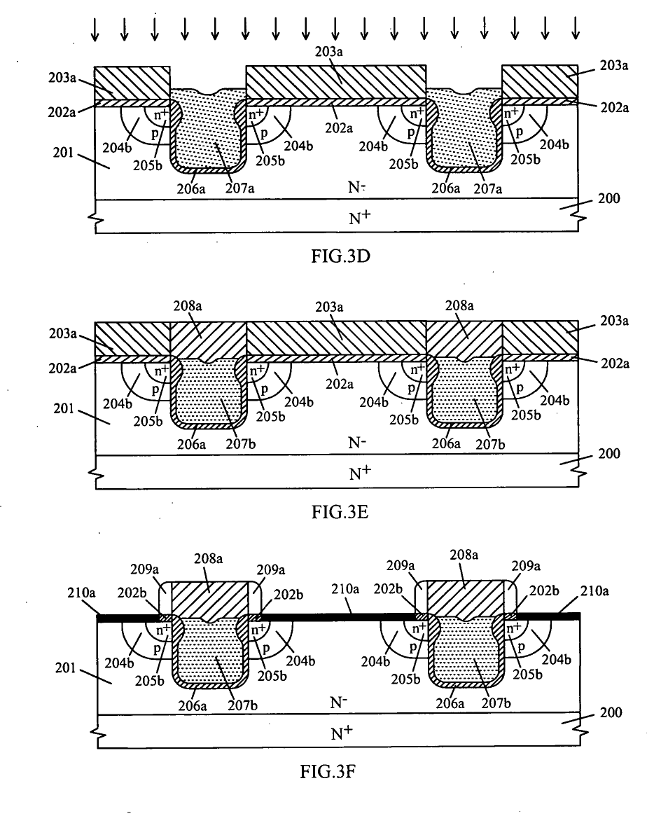

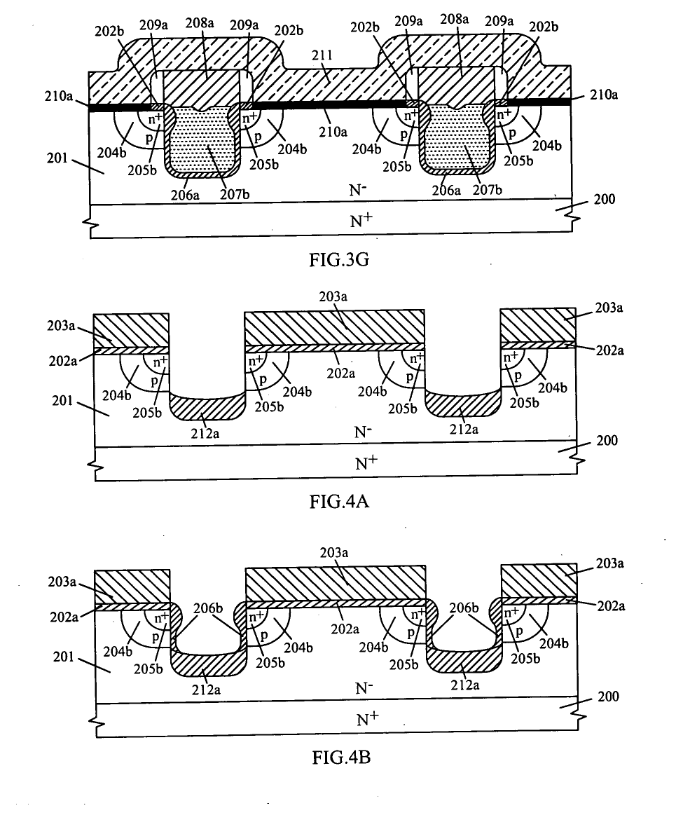

Referring now to FIG. 3A through FIG. 3G, there are shown process steps and their schematic cross-sectional views of fabricating a first-type self-aligned Schottky-barrier clamped trench DMOS transistor structure of the present invention.

FIG. 3A shows that a lightly-doped N⁻ epitaxial silicon layer 201 is formed on a heavily-doped N⁺ silicon substrate 200; a buffer oxide layer 202 is then formed on the lightly-doped N⁻ epitaxial silicon layer 201; subsequently, a masking dielectric layer 203 is formed on the buffer oxide layer 202; and thereafter, a first masking photoresist (PR1) step is performed to define a plurality of self-aligned source regions (SR) and a trench gate region (TGR) as shown in FIG.3B, wherein each of the plurality of self-aligned source regions (SR) is surrounded by the trench gate region (TGR).The heavily-doped N⁺ silicon substrate 200 is preferably to have a resistivity between 0.001 Ω*cm and 0.004 Ω*cm and a thickness between 300 μm and 800 μm, depending on wafer size. The lightly-doped N⁻ epitaxial silicon layer 201 is preferably to have a resistivity between 0.1 Ω*cm and 100 Ω*cm and a thickness between 1 μm and 100 Ωm. The buffer oxide layer 202 is preferably a thermal silicon dioxide layer and its thickness is preferably between 200 Angstroms and 1000 Angstroms. It should be noted that the shape of each of the plurality of self-aligned source regions (SR) can be square, rectangular, hexagonal, circular or cylindrical, so forth.

FIG. 3B shows that the masking dielectric layer 203 in the trench gate region(TGR) is removed by using anisotropic dry etching to form a plurality of patterned masking dielectric layers 203a and the patterned masking photoresist (PRI) are then removed; boron ion-implantation is performed through a patterned window in the trench gate region (TGR) and a drive-in process is performed to form a p-diffusion region 204a in the lightly-doped N⁻ epitaxial silicon layer 201; arsenic or phosphorous ion-implantation is then performed through the same patterned window and a drive-in process is performed to form a n⁺ diffusion region 205a in a surface portion of the p-diffusion region 204a. The implant dose of the boron ion-implantation is preferably between 10¹³/cm² and 5*10¹⁴/cm² and, therefore, the p-diffusion region 204a is moderately-doped with a junction depth between 0.8 μm and 3 μm. The phosphorous or arsenic implant dose is preferably between 10¹⁵/cm² and 10¹⁶/cm² and, therefore, the n⁺ diffusion region 205a is heavily-doped with a junction depth between 0.2 μm and 1 μm.

FIG.3C shows that the buffer oxide layer 202 in the trench gate region (TGR) is removed by using anisotropic dry etching or wet etching and a shallow trench is then formed in the lightly-doped N⁻ epitaxial silicon layer 201 by using anisotropic dry etching; a cleaning process is then performed to remove trenched defects on the trenched silicon surface; and subsequently, a gate dielectric layer 206a is formed over the trenched silicon surface. It should be noted that the cleaning process includes to grow a liner oxide layer over the trenched silicon surface and then to remove the liner oxide layer. The gate dielectric layer 206a is preferably a thermal silicon dioxide layer or a thermal silicon dioxide layer nitrided in a N2O ambient and its thickness is preferably between 100 Angstroms and 1000 Angstroms. From FIG. 3C, it is clearly seen that a thicker oxide layer is formed over a heavily-doped n⁺ source diffusion ring 205b and the p-diffusion region 204a in FIG. 3B is divided by the shallow trench into a moderately-doped p-base diffusion ring 204b in each of the plurality of self-aligned source regions (SR). Moreover, it is clearly seen that the depth of the shallow trench is slightly deeper than the junction depth of the p-diffusion region 204a. It should be emphasized that the thicker oxide layer over the heavily-doped n⁺ source diffusion ring 205b is favorable to offer a good separation between the heavily-doped n⁺ source diffusion ring 205b and the conductive gate layer formed later on.

FIG. 3D shows that an etched-back polycrystalline-silicon layer 207a is formed over the gate dielectric layer 206a in the trench gate region (TGR) and is then heavily implanted with a high dose of phosphorous or arsenic doping impurities in a self-aligned manner. The etched-back polycrystalline -silicon layer 207a is formed by first depositing a polycrystalline-silicon layer 207 (not shown) using LPCVD with a thickness approximately equal to or larger than one half width of the trench gate region (TGR) and then etching back the deposited polycrystalline-silicon layer 207 to a level slightly higher then a top surface level of the patterned buffer oxide layer 202a.

FIG. 3E shows that a thermal oxidation process is performed to oxidize the etched-back heavily-doped polycrystalline-silicon layer 207a to form a planarized capping oxide layer 208a in the trench gate region (TGR) and simultaneously redistribute doping impurities in a self-aligned heavily-doped polycrystalline-silicon gate layer 207b. It should be noted that the planarized capping oxide layer 208a can be formed to have a top surface level higher than the patterned masking dielectric layer 203a in each of the plurality of self-aligned source regions (SR) and a top surface level of the self-aligned heavily-doped polycrystalline-silicon gate layer 207b is located at an upper portion of the thicker oxide layer of the gate dielectric layer 206a.

FIG. 3F shows that the patterned masking dielectric layer 203a in each of the plurality of self-aligned source regions (SR) are removed by hot-phosphoric acid or anisotropic dry etching; a sidewall dielectric spacer 209a is formed over a sidewall of the planarized capping oxide layer 208a in the trench gate region (TGR) and on a side surface portion 202b of the patterned buffer oxide layer 202a in each of the plurality of self-aligned source regions (SR); and the patterned buffer oxide layer 202a surrounded by the sidewall dielectric spacer 209a in each of the plurality of self-aligned source regions (SR) is removed by anisotropic dry etching or buffered hydrofluoric acid to form a self-aligned source contact window in each of the plurality of self-aligned source regions (SR); and subsequently, a self-aligned metal silicide layer 210a is formed over the self-aligned source contact window by using a well-known self-aligned silicidation process. The sidewall dielectric spacer 209a is preferably made of silicon nitride as deposited by LPCVD and is formed by first depositing a silicon nitride layer 209 (not shown) over a formed structure surface and then etching back a thickness of the deposited silicon nitride layer 209. The self-aligned metal silicide layer 210a is preferably a refractory metal silicide layer, such as titanium silicide, cobalt silicide or nickel silicide.

FIG. 3G shows that a source metal layer 211 is formed over a formed structure surface. The source metal layer 211 comprises a metal layer over a barrier metal layer. The metal layer comprises a silver (Ag) or aluminum (Al) layer and the barrier metal layer comprises a refractory metal layer or a refractory metal nitride layer.

From FIG. 3G, it is clearly seen that a Schottky-barrier diode is formed by the self-aligned metal silicide layer 210a on the lightly-doped N⁻ epitaxial silicon layer 201 surrounded by the moderately-doped p-base diffusion ring 204b in each of the plurality of self-aligned source regions (SR) and the moderately-doped p-base diffusion ring 204b is acted as a diffusion guard ring of the Schottky-barrier contact metal layer 210a to eliminate edge leakage current and soft breakdown of the Schottky-barrier diode. Moreover, the moderately-doped p-base diffusion ring 204b is shorted to the heavily-doped n⁺ source diffusion ring 205b to eliminate the body effect on threshold voltage of trench-type DMOS transistor cells. In addition, the lightly-doped N⁻ epitaxial silicon layer 201 surrounded by the moderately-doped p-base diffusion ring 204b can be fully depleted by a depletion region of a p-n junction formed between the moderately-doped p-base diffusion ring 204b and the lightly-doped N⁻ epitaxial silicon layer 201 under a forward blocking state to eliminate a large reverse leakage current of the Schottky-barrier diode with a low barrier height due to a well-known image-force lowering effect.

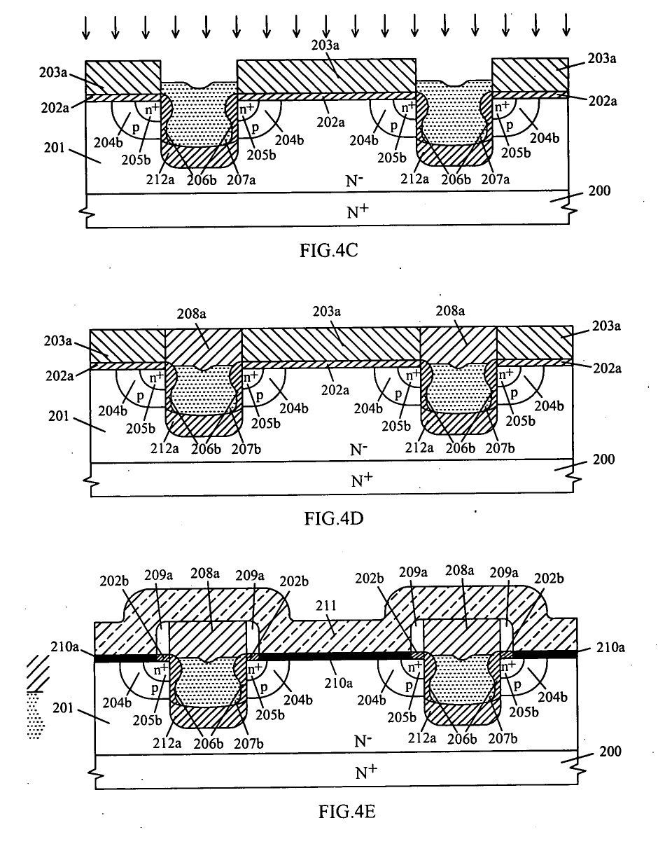

Referring now to FIG. 4A through FIG. 4E, there are shown simplified process steps after FIG. 3B and their schematic cross-sectional views of fabricating a second-type self-aligned Schottky-barrier clamped trench DMOS transistor structure of the present invention.

FIG. 4A shows that a thicker isolation dielectric layer 212a is formed on a bottom silicon surface of the shallow trench after forming the shallow trench. The thicker isolation dielectric layer 212a is preferably made of silicon dioxide as deposited by LPCVD and is formed by first depositing a silicon dioxide layer 212(not shown) with a thickness approximately equal to or slightly larger than one half width of the trench gate region (TGR) to fill a gap in the shallow trench and then etching-back the deposited silicon dioxide layer 212 to approximately a bottom level of the moderately-doped p-base diffusion ring 204b by using anisotropic dry etching.

FIG. 4B shows that a gate dielectric layer 206b is formed over sidewalls of trenched silicon surfaces. Similarly, a thicker dielectric layer is formed over a trenched silicon surface of the heavily-doped n⁺ source diffusion ring 205b. It should be noted that a cleaning process can be performed to eliminate trench-induced defects before forming the thicker isolation dielectric layer 212a or after forming the thicker isolation dielectric layer 212a.

FIG. 4C shows that an etched-back polycrystalline-silicon layer 207a is formed over the gate dielectric layer 206b and on the thicker isolation dielectric layer 212a; and subsequently, ion implantation is performed to heavily dope the etched-back crystalline-silicon layer 207a in a self-aligned manner.

FIG. 4D shows that a thermal oxidation process is performed to form a planarized capping oxide layer 208a in the trench gate region (TGR) as described in FIG. 3E.

Following the process steps as shown in FIG. 3F and FIG. 3G, FIG. 4E can be obtained. Apparently, FIG. 4E is quite similar to FIG. 3G except that a thicker isolation dielectric layer 212a is formed on the bottom silicon surface of the shallow trench to reduce gate to drain capacitance and to increase gate to drain breakdown voltage.

Referring now to FIG. 5A and FIG. 5B, there are shown simplified process steps after FIG. 3C and their schematic cross-sectional views of fabricating a third-type self-aligned Schottky-barrier clamped trench DMOS transistor structure of the present invention.

FIG. 5A shows that a self-aligned heavily-doped polycrystalline-silicon gate layer 207b is formed over the gate dielectric layer 206a; a pair of capping sidewall dielectric spacers 213a are formed over sidewalls of the patterned masking dielectric layers 203a and on side surface portions of the self-aligned heavily-doped polycrystalline-silicon gate layer 207b; a self-aligned highly conductive layer 214a is formed on the self-aligned heavily-doped polycrystalline-silicon gate layer 207b between the pair of capping sidewall dielectric spacers 213a; and subsequently, a planarized capping oxide layer 208b is then formed on the self-aligned highly conductive layer 214a. The pair of capping sidewall dielectric spacers 213a are preferably made of silicon dioxide as deposited by LPCVD and are formed by first depositing a silicon dioxide layer 213 (not shown) over a formed structure surface and then etching back a thickness of the deposited silicon dioxide layer 213. The self-aligned highly conductive layer 214a can be a metal silicide layer being formed by a well-known self-aligned silicidation process or an etched-back refractory metal silicide or refractory metal layer being formed by first depositing a refractory metal silicide or refractory metal layer to fill a gap between the pair of capping sidewall dielectric spacers 213a and then etching back the deposited refractory metal silicide or refractory metal layer to a predetermined thickness. The metal silicide layer is preferably made of titanium silicide, cobalt silicide or nickle silicide. The refractory metal silicide layer is preferably made of tungsten silicide and the refractory metal layer is preferably made of tungsten. The planarized capping oxide layer 208b is preferably made of silicon dioxide as deposited by LPCVD and is formed by first depositing a silicon dioxide layer 208 (not shown) to fill a gap between the pair of capping sidewall dielectric spacers 213a and then etching back a thickness of the deposited silicon dioxide layer 208 or planarizing the deposited silicon dioxide layer 208 using chemical mechanical polishing (CMP) with the patterned masking dielectric layer 203a as a polishing stop. It should be noted that the self-aligned heavily-doped polycrystalline-silicon gate layer 207b can be heavily implanted with a high dose of arsenic or phosphorous doping impurities before or after forming the pair of capping sidewall dielectric spacers 213a.

Following the same process steps shown in FIG. 3F and FIG. 3G, FIG. 5B can be easily obtained. From FIG. 5B, it is clearly seen that the self-aligned highly conductive layer 214a being formed on the self-aligned heavily-doped polycrystalline-silicon gate layer 207b between the pair of capping sidewall dielectric spacers 213a may effectively reduce gate-interconnection parasitic resistance, as compared to FIG. 3G Moreover, the pair of capping sidewall dielectric spacers 213a shown in FIG. 5B may eliminate possible leakage paths between the heavily-doped n⁺ source diffusion rings 205b and the conductive gate layer 207b/214a.

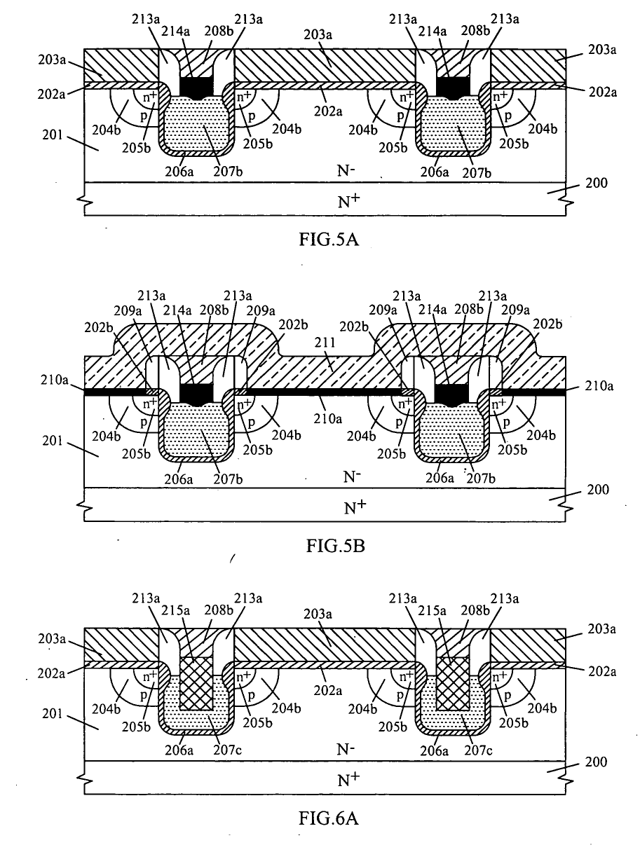

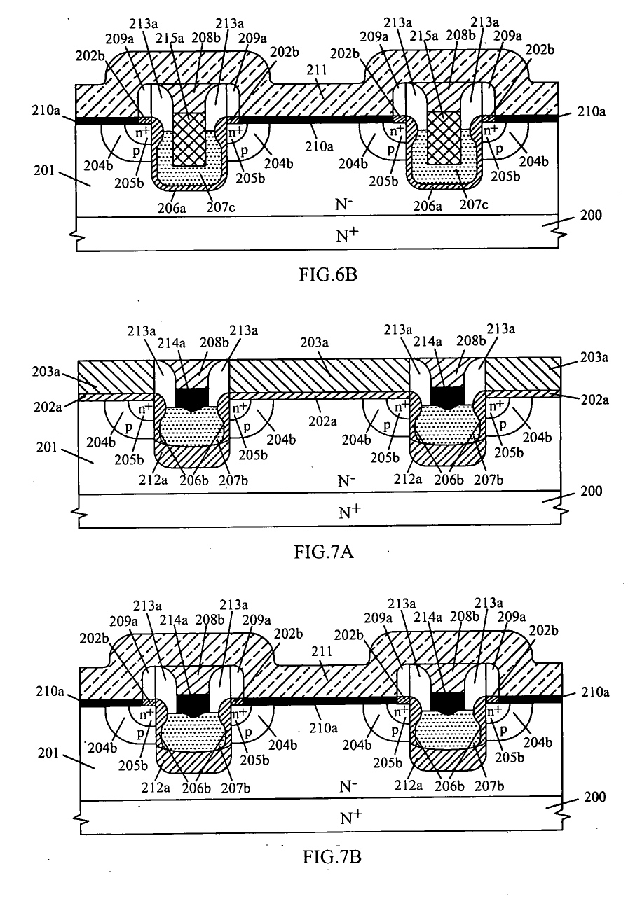

Referring now to FIG. 6A and FIG. 6B, there are shown simplified process steps after FIG. 3C and their schematic cross-sectional views of fabricating a fourth-type self-aligned Schottky-barrier clamped trench DMOS transistor structure of the present invention.

FIG. 6A shows that a self-aligned heavily-doped polycrystalline-silicon gate layer 207b is formed over the gate dielectric layer 206a and a pair of capping sidewall dielectric spacers 213a are formed, as described in FIG. 5A; the self-aligned heavily-doped polycrystalline-silicon gate layer 207b between the pair of capping sidewall dielectric spacers 213a is etched to form a trenched heavily-doped polycrystalline-silicon gate layer 207c by using anisotropic dry etching; an etched-back conductive layer 215a is then formed to fill a portion of a gap between the pair of capping sidewall dielectric spacers 213a; and subsequently, a planarized capping oxide layer 208b is formed on the etched-back conductive layer 215a. The etched-back conductive layer 215a is preferably made of tungsten silicide or tungsten and is formed by depositing a conductive layer 215 (not shown) to fill a gap between the pair of capping sidewall dielectric spacers 213a and then etching back the deposited conductive layer 215 to a predetermined depth. Similarly, the planarized capping oxide layer 208b is formed by the same process as described in FIG. 5A.

Following the same process steps shown in FIG. 3F and FIG. 3G, FIG. 6B can be easily obtained. From FIG. 6B, it is clearly seen that the etched-back conductive layer 215a may further reduce the gate-interconnection parasitic resistance as compared to FIG. 5B.

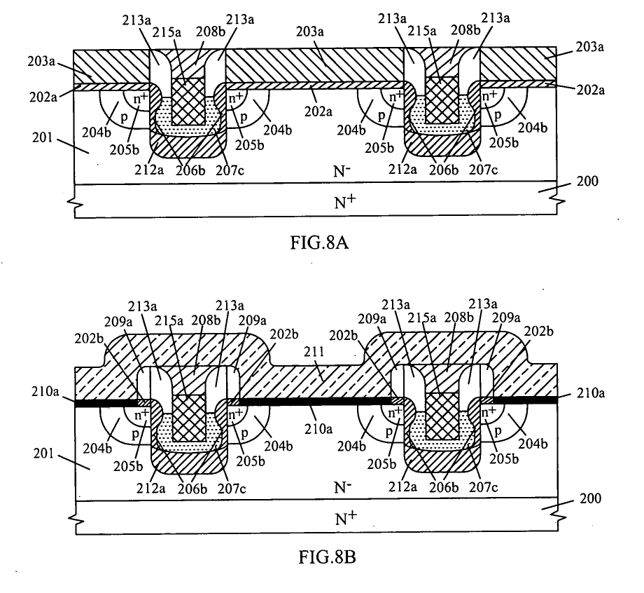

Referring now to FIG. 7A and FIG. 7B, there are shown simplified process steps after FIG. 4B and their schematic cross-sectional views of fabricating a fifth-type self-aligned Schottky-barrier clamped trench DMOS transistor structure of the present invention.

FIG. 7A shows that a self-aligned heavily-doped polycrystalline-silicon gate layer 207b is formed over the gate dielectric layers 206b and the thicker isolation dielectric layer 212a; a pair of capping sidewall dielectric spacers 213a is then formed over sidewalls of the patterned masking dielectric layers 203a and on side surface portions of the self-aligned heavily-doped polycrystalline-silicon gate layer 207b; a self-aligned highly conductive layer 214a is formed on the self-aligned heavily-doped polycrystalline-silicon gate layer 207b between the pair of capping sidewall dielectric spacers 213a; and subsequently, a planarized capping oxide layer 208b is then formed on the self-aligned highly conductive layer 214a. Basically, the process steps for forming FIG. 7A are the same as those for forming FIG. 6A except that a thicker isolation dielectric layer 212a is formed on the bottom trenched silicon surface of the shallow trench, and therefore a further description is omitted.

Following the same process steps shown in FIG. 3F and FIG. 3G, FIG. 7B can be easily obtained. Compared FIG. 7B and FIG. 4E, it is clearly seen that FIG. 7B offers the self-aligned highly conductive layer 214a to reduce the gate-interconnection parasitic resistance.

Referring now to FIG. 8A and FIG. 8B, there are shown simplified process steps after FIG. 4B and their schematic cross-sectional views of fabricating a sixth-type self-aligned Schottky-barrier clamped trench DMOS transistor structure of the present invention.

FIG. 8A shows that a self-aligned heavily-doped polycrystalline-silicon gate layer 207b is formed over the gate dielectric layer 206b and the thicker isolation dielectric layer 212a; a pair of capping sidewall dielectric spacers 213a are formed over sidewalls of the patterned masking dielectric layers 203a and on side surface portions of the self-aligned heavily-doped polycrystalline-silicon gate layer 207b; the self-aligned heavily-doped polycrystalline-silicon gate layer 207b between the pair of capping sidewall dielectric spacers 213a is anisotropically etched to form a trenched heavily-doped polycrystalline-silicon gate layer 207c; an etched-back conductive layer 215a is formed to fill a portion of a gap between the pair of capping sidewall dielectric spacers 213a; and subsequently, a planarized capping oxide layer 208b is formed on the etched-back conductive layer 215a. Basically, the process steps for forming FIG. 8A are the same as those for forming FIG. 6A except that the thicker isolation dielectric layer 212a is formed on the bottom trenched silicon surface of the shallow trench, and therefore a further description is omitted.

Following the same process steps shown in FIG. 3F and FIG. 3G, FIG. 8B can be easily obtained. Compared FIG. 8B and FIG. 7B, it is clearly seen that FIG. 8B offers the etched-back conductive layer 215a to further reduce the gate-interconnection parasitic resistance.

Based on the above descriptions, the advantages and features of the present invention are summarized below:
(a) The self-aligned Schottky-barrier clamped trench DMOS transistor structure of the present invention offers a self-aligned Schottky-barrier diode being formed in a middle portion of a self-aligned source region without critical masking photoresist steps.
(b) The self-aligned Schottky-barrier clamped trench DMOS transistor structure of the present invention offers a self-aligned Schottky-barrier diode with a moderately-doped p-base diffusion ring acted as a diffusion guard ring to eliminate edge leakage current and soft breakdown of the self-aligned Schottky-barrier diode.
(c) The self-aligned Schottky-barrier clamped trench DMOS transistor structure of the present invention offers a self-aligned source metal silicide layer to short a heavily-doped n⁺ source diffusion ring and a moderately-doped p-base diffusion ring to eliminate the body effect of trench DMOS transistor cells and simultaneously to act as a self-aligned Schottky-barrier contact metal layer.
(d) The self-aligned Schottky-barrier clamped trench DMOS transistor structure of the present invention offers a reversely-biased p-n junction formed by a moderately-doped p-base diffusion ring and a lightly-doped N⁻ epitaxial semiconductor layer to pinch the lightly-doped N⁻ epitaxial semiconductor layer under the self-aligned Schottky-barrier contact metal layer, so a high reverse leakage current of a low Schottky-barrier height due to image force lowering can be eliminated.
(e) The self-aligned Schottky-barrier clamped trench DMOS transistor structure of the present invention offers a pair of capping sidewall dielectric spacers on side surface portions of a self-aligned heavily-doped polycrystalline-silicon gate layer to eliminate leakage current paths between a self-aligned heavily-doped n⁺ source diffusion ring and the self-aligned heavily-doped polycrystalline-silicon gate layer.
(f) The self-aligned Schottky-barrier clamped trench DMOS transistor structure of the present invention offers a self-aligned highly conductive layer being formed on the self-aligned heavily-doped polycrystalline-silicon gate layer between the pair of capping sidewall dielectric spacers or an etched-back conductive layer being formed in a trenched heavily-doped polycrystalline-silicon gate layer between the pair of capping sidewall dielectric spacers to reduce the gate-interconnection parasitic resistance.
(g) The self-aligned Schottky-barrier clamped trench DMOS transistor structure of the present invention offers a thicker isolation dielectric layer being formed on a bottom trench semiconductor surface of the shallow trench to reduce gate to drain capacitance and to increase breakdown voltage between gate and drain electrodes.

The self-aligned Schottky-barrier clamped trench n-channel DMOS transistor structures as described can be easily applied to fabricate self-aligned Schottky-barrier clamped trench p-channel DMOS transistor structures by changing doping types in semiconductor regions. Similarly, the self-aligned Schottky-barrier clamped trench DMOS transistor structures can be extended to fabricate insulated-gate bipolar transistors (IGBT) and MOS-controlled thyristors (MCT).

While the present invention has been particularly shown and described with reference to the present examples and embodiments as considered as illustrative and not restrictive. Moreover, the present invention is not to be limited to the details given herein, it will be understood by those skilled in the art that various changes in forms and details may be made without departure from the true spirit and scope of the present invention.

What is claimed is:

1. A self-aligned Schottky-barrier clamped trench DMOS transistor structure, comprising:
a semiconductor substrate of a first conductivity type, wherein the semiconductor substrate comprises a lightly-doped epitaxial semiconductor layer being formed on a heavily-doped semiconductor substrate;
a self-aligned source region being formed in the lightly-doped epitaxial semiconductor layer surrounded by a trench gate region, wherein the self-aligned source region comprises a moderately-doped base diffusion ring of a second conductivity type being formed in a side surface portion of the lightly-doped epitaxial semiconductor layer, a heavily-doped source diffusion ring of the first conductivity type being formed in a side surface portion of the moderately-doped base diffusion ring, and a self-aligned source contact window being formed on the lightly-doped epitaxial semiconductor layer surrounded by the moderately-doped base diffusion ring, the moderately-doped base diffusion ring surrounded by the heavily-doped source diffusion ring, and the heavily-doped source diffusion ring surrounded by a sidewall dielectric spacer;
the trench gate region being formed in the lightly-doped epitaxial semiconductor layer through a patterned window, wherein the trench gate region comprises a shallow trench being formed to divide a heavily-doped diffusion region of the first conductivity type into the heavily-doped source diffusion ring and a moderately-doped diffusion region of the second conductivity type into the moderately-doped base diffusion ring, a gate dielectric layer being formed over a trenched semiconductor surface, a self-aligned highly conductive gate layer being formed over the gate dielectric layer, and a capping dielectric layer being formed on the self-aligned highly conductive gate layer; and
a source metal layer being at least formed over the self-aligned source contact window.

2. The self-aligned Schottky-barrier clamped trench DMOS transistor structure according to claim 1, wherein the sidewall dielectric spacer being made of silicon nitride is formed over a sidewall of the capping dielectric layer in the trench gate region and on a side surface portion of a buffer oxide layer in the self-aligned source region.

3. The self-aligned Schottky-barrier clamped trench DMOS transistor structure according to claim 1, wherein the patterned window is formed by removing a masking dielectric layer on a buffer oxide layer in the trench gate region using a masking photoresist step.

4. The self-aligned Schottky-barrier clamped trench DMOS transistor structure according to claim 1, wherein the moderately-doped diffusion region for forming the moderately-doped base diffusion ring is formed by implanting a moderate dose of doping impurities into the lightly-doped epitaxial semiconductor layer through the patterned window.

5. The self-aligned Schottky-barrier clamped trench DMOS transistor structure according to claim 1, wherein the heavily-doped diffusion region for forming the heavily-doped source diffusion ring is formed by implanting a high dose of doping impurities into a surface portion of the moderately-doped diffusion region through the patterned window.

6. The self-aligned Schottky-barrier clamped trench DMOS transistor structure according to claim 1, wherein a thicker isolation dielectric layer is formed on a bottom trenched semiconductor surface and the self-aligned highly conductive gate layer is formed over the gate dielectric layer and on the thicker isolation dielectric layer.

7. The self-aligned Schottky-barrier clamped trench DMOS transistor structure according to claim 1, wherein the self-aligned highly conductive gate layer comprises a self-aligned heavily-doped polycrystalline-silicon gate layer with a thermal oxide layer being formed on the self-aligned heavily-doped polycrystalline-silicon gate layer to act as the capping dielectric layer.

8. The self-aligned Schottky-barrier clamped trench DMOS transistor structure according to claim 1, wherein the self-aligned highly conductive gate layer comprises a self-aligned heavily-doped polycrystalline-silicon gate layer and a self-aligned refractory metal silicide or refractory metal layer being formed on the self-aligned heavily-doped polycrystalline-silicon gate layer between a pair of capping sidewall dielectric spacers and the capping dielectric layer comprises the pair of capping sidewall dielectric spacers and a planarized capping oxide layer being formed between the pair of capping sidewall dielectric spacers.

9. The self-aligned Schottky-barrier clamped trench DMOS transistor structure according to claim 1, wherein the self-aligned highly conductive gate layer comprises a self-aligned trenched heavily-doped polycrystalline-silicon gate layer and an etched-back self-aligned refractory metal silicide or refractory metal layer being formed over the self-aligned trenched heavily-doped polycrystalline-silicon gate layer between a pair of capping sidewall dielectric spacers and the capping dielectric layer comprises the pair of capping sidewall dielectric spacers and a planarized capping oxide layer being formed between the pair of capping sidewall dielectric spacers.

10. The self-aligned Schottky-barrier clamped trench DMOS transistor structure according to claim 1, wherein the source metal layer comprises a self-aligned metal silicide layer being formed over the self-aligned source contact window and a metal layer over a barrier-metal layer being at least formed over the self-aligned metal silicide layer.

11. A self-aligned Schottky-barrier clamped trench DMOS transistor structure, comprising:
a single crystalline-silicon substrate of a first conductivity type, wherein the single crystalline-silicon substrate comprises a lightly-doped epitaxial silicon layer being formed on a heavily-doped silicon substrate;
a self-aligned source region being formed in the lightly-doped epitaxial silicon layer surrounded by a trench gate region, wherein the self-aligned source region comprises a moderately-doped base diffusion ring of a second conductivity type being formed in a side portion of the lightly-doped epitaxial silicon layer, a heavily-doped source diffusion ring of the first conductivity type being formed in a side surface portion of the moderately-doped base diffusion ring, and a self-aligned source contact window being formed on the lightly-doped epitaxial silicon layer surrounded by the moderately-doped base diffusion ring, the moderately-doped base diffusion ring surrounded by the heavily-doped source diffusion ring, and the heavily-doped source diffusion ring surrounded by a sidewall dielectric spacer formed over a sidewall of the trench gate region and on a side surface portion of a buffer oxide layer;
the trench gate region being defined by a masking photoresist step to form a patterned window for sequentially forming a moderately-doped diffusion region of the second conductivity type in the lightly-doped epitaxial silicon layer and a heavily-doped diffusion region of the first conductivity type in a surface portion of the moderately-doped diffusion region, wherein the trench gate region further comprises a shallow trench being used to divide the heavily-doped diffusion region into the heavily-doped source diffusion ring and the moderately-doped diffusion region into the moderately-doped base diffusion ring, a gate dielectric layer being formed over a trenched silicon surface of the shallow trench, a self-aligned highly conductive gate layer being formed over the gate dielectric layer, and a capping dielectric layer being formed on the self-aligned highly conductive gate layer; and
a source metal layer being at least formed over the self-aligned source contact window, wherein the source metal layer comprises a self-aligned metal silicide layer being formed over the self-aligned source contact window and a metal layer over a barrier metal layer being at least formed over the self-aligned metal silicide layer.

12. The self-aligned Schottky-barrier clamped trench DMOS transistor structure according to claim 1, wherein the patterned window is formed by removing a masking dielectric layer on the buffer oxide layer in the trench gate region and is used as a self-aligned implantation window for sequentially forming the moderately-doped diffusion region and the heavily-doped diffusion region.

13. The self-aligned Schottky-barrier clamped trench DMOS transistor structure according to claim 11, wherein the self-aligned highly conductive gate layer comprises a self-aligned heavily-doped polycrystalline-silicon gate layer or a self-aligned heavily-doped polycrystalline-silicon gate layer being capped with a self-aligned refractory metal silicide or refractory metal layer formed between a pair of capping sidewall dielectric spacers.

14. The self-aligned Schottky-barrier clamped trench DMOS transistor structure according to claim 11, wherein the self-aligned conductive gate layer comprises a self-aligned trenched heavily-doped polycrystalline-silicon gate layer and an etched-back self-aligned refractory metal silicide or refractory metal layer being formed over the self-aligned trenched heavily-doped polycrystalline-silicon gate layer between a pair of capping sidewall dielectric spacers.

15. A self-aligned Schottky-barrier clamped trench DMOS transistor structure, comprising:
a single crystalline-silicon substrate of a first conductivity type, wherein the single crystalline-silicon substrate comprises a lightly-doped epitaxial silicon layer being formed on a heavily-doped silicon substrate;
a self-aligned source region being formed in the lightly-doped epitaxial silicon layer surrounded by a trench gate region, wherein the self-aligned source region comprises a moderately-doped base diffusion ring of a second conductivity type being formed in a side portion of the lightly-doped epitaxial silicon layer, a heavily-doped source diffusion ring of the first conductivity type being formed in a side surface portion of the moderately-doped base diffusion ring, and a self-aligned source contact window being formed on the lightly-doped epitaxial silicon layer surrounded by the moderately-doped base diffusion ring, the moderately-doped base diffusion ring surrounded by the heavily-doped source diffusion ring, and the heavily-doped source diffusion ring surrounded by a sidewall dielectric spacer;
the trench gate region being defined by a masking photoresist step to form a patterned window for sequentially forming a moderately-doped diffusion region of the second conductivity type in the lightly-doped epitaxial silicon layer and a heavily-doped diffusion region of the first conductivity type in a surface portion of the moderately-doped diffusion region, where the trench gate region further comprises a shallow trench being used to divide the heavily-doped diffusion region into the heavily-doped source diffusion ring and the moderately-doped diffusion region into the moderately-doped base diffusion ring, a thicker isolation dielectric layer being formed on a bottom trenched silicon surface of the shallow trench and a gate dielectric layer being formed over each sidewall of the shallow trench, a self-aligned highly conductive gate layer being formed over the gate dielectric layer and on the thicker dielectric layer, and a capping dielectric layer being formed on the self-aligned highly conductive gate layer; and
a source metal layer being at least formed over the self-aligned source contact window, wherein the source metal layer comprises a self-aligned refractory metal silicide layer being formed over the self-aligned source contact window and a metal layer over a barrier metal layer being at least formed over the self-aligned refractory metal silicide layer.

16. The self-aligned Schottky-barrier clamped trench DMOS transistor structure according to claim 15, wherein the sidewall dielectric spacer being made of silicon nitride is formed over a sidewall of the capping dielectric layer in the trench gate region and on a side surface portion of a buffer oxide layer in the self-aligned source region.

17. The self-aligned Schottky-barrier clamped trench DMOS transistor structure according to claim 15, wherein the self-aligned highly conductive gate layer comprises a self-aligned heavily-doped polycrystalline-silicon gate layer capped with a thermal oxide layer being acted as the capping dielectric layer.

18. The self-aligned Schottky-barrier clamped trench DMOS transistor structure according to claim 15, wherein the self-aligned highly conductive gate layer comprises a self-aligned heavily-doped polycrystalline-silicon gate layer capped with a self-aligned refractory metal silicide or refractory metal layer being formed between a pair of capping dielectric spacers.

19. The self-aligned Schottky-barrier clamped trench DMOS transistor structure according to claim 15, wherein the self-aligned highly conductive gate layer comprises a self-aligned trenched heavily-doped polycrystalline-silicon layer and an etched-back refractory metal silicide or refractory metal layer being formed over the self-aligned trenched heavily-doped polycrystalline-silicon gate layer between a pair of capping sidewall dielectric spacers.

20. The self-aligned Schottky-barrier clamped trench DMOS transistor structure according to claim 15, wherein the thicker isolation dielectric layer being made of silicon dioxide is formed by first depositing a silicon dioxide layer to fill the shallow trench and then etching back the deposited silicon dioxide layer to a depth equal to or lower than a junction depth of the moderately-doped base diffusion ring.
